(19) United States
(12) Patent Application Publication
(10) Pub. No.: US 2024/0356303 A1
(43) Pub. Date: Oct. 24, 2024

(54) PHOTONIC INTEGRATED CIRCUIT DEVICE AND FABRICATION METHOD OF THE SAME

(71) Applicant: ELECTRONICS AND TELECOMMUNICATIONS RESEARCH INSTITUTE, Daejeon (KR)

(72) Inventors: Seungchul LEE, Daejeon (KR); Namje KIM, Daejeon (KR); O-Kyun KWON, Daejeon (KR); Miran PARK, Daejeon (KR)

(73) Assignee: ELECTRONICS AND TELECOMMUNICATIONS RESEARCH INSTITUTE, Daejeon (KR)

(21) Appl. No.: 18/638,137

(22) Filed: Apr. 17, 2024

(30) Foreign Application Priority Data
Apr. 20, 2023 (KR) 10-2023-0051895

(51) Int. Cl. H01S 5/026; H01S 5/343

(52) U.S. Cl. CPC H01S 5/026; H01S 5/34313

(57) ABSTRACT

Disclosed are a photonic integrated circuit device and a fabrication method thereof, wherein the fabrication method includes forming an active layer on a substrate having a passive waveguide region, an LD region, and an EAM region, forming a grating layer, forming a first upper clad layer, forming a passivation layer, forming a mask pattern, forming a vacancy generation layer, performing a rapid thermal process to provide a first vacancy activation region in the active layer, removing the vacancy generation layer, the mask pattern, and the passivation layer, forming a second upper clad layer, and forming electrodes.

### CROSS-REFERENCE TO RELATED APPLICATIONS

This U.S. non-provisional patent application claims priority under 35 U.S.C. § 119 of Korean Patent Application No. 10-2023-0051895, filed on Apr. 20, 2023, the entire contents of which are hereby incorporated by reference.

### BACKGROUND

The present disclosure herein relates to a photonic integrated circuit device and a fabrication method of the same, and more particularly, to a photonic integrated circuit device for optical communication and a fabrication method of the same. The present disclosure also includes a technology for improving the characteristics of an optical modulator.

Nowadays, a device and a network technology are actively studied in relation to advancement in optical link technology for mobile/Internet access in optical communication. Furthermore, a technology related to an analog as well as digital communication device attracts interest in optical communication. In particular, it is important to develop an optical device having excellent high-speed, high-output, and high-temperature operating characteristics in order to construct future 5G+ and 6G ultra high speed, hyper-connected, and ultra-low latency mobile/Internet access networks. To this end, unit devices such as lasers, optical modulators, optical waveguides, optical amplifiers and the like are necessary. In this field, a photonic integrated circuit device fabrication technology is preferred to integrate and fabricate the unit devices into a single chip.

### SUMMARY

The present disclosure provides a method for fabricating a photonic integrated circuit device capable of improving the modulation characteristics of devices as well as increasing the productivity and the production yield thereof.

An embodiment of the inventive concept provides a method for fabricating a photonic integrated circuit device, the method including: forming an active layer on a substrate having a passive waveguide region, a laser diode (LD) region on one side of the passive waveguide region, and an electro-absorption modulation (EAM) region of another side of the passive waveguide region; forming a grating layer on the active layer; forming a first upper clad layer on the grating layer; forming a passivation layer on the first upper clad layer; forming a mask pattern configured to expose a portion of the passivation layer in the passive waveguide region and the EAM region; forming a vacancy generation layer on the mask pattern and the passivation layer; performing a rapid thermal process on the substrate to form a first vacancy activation region in the active layer in a portion of the passive waveguide region and the EAM region; removing the vacancy generation layer, the mask pattern, and the passivation layer; forming a second upper clad layer on the first upper clad layer; and forming electrodes on the second upper clad layer in the LD region and the EAM region.

In an embodiment, the mask pattern may include silicon oxide formed by a plasma-enhanced chemical vapor deposition (PECVD) method.

In an embodiment, the vacancy generation layer may include silicon oxide formed by a sputtering method.

In an embodiment, the active layer may include a multi-quantum well layer.

In an embodiment, the multi-quantum well layer may include InAlGaAs.

In an embodiment, the first upper clad layer may include InP.

In an embodiment, the passivation layer may include InGaAs.

In an embodiment, the method for fabricating a photonic integrated circuit device may further include forming a separate confinement heterostructure (SCH) layer between the active layer and the grating layer.

In an embodiment, the mask pattern may include: a first thickness region; and a second thickness region thinner than the first thickness region.

In an embodiment, the active layer may further include a second vacancy activation region formed in the EAM region and adjacent to the first vacancy activation region.

In an embodiment of the inventive concept, a method for fabricating a photonic integrated circuit device includes: forming an active layer on a substrate having a passive waveguide region, a laser diode (LD) region on one side of the passive waveguide region, and an electro-absorption modulation (EAM) region of another side of the passive waveguide region; forming a grating layer on the active layer; forming a passivation layer on the grating layer; using, as a deposition mask, a mask pattern configured to expose a portion of the passivation layer in the passive waveguide region and the EAM region to form a vacancy generation layer on the passivation layer; performing a rapid thermal process on the substrate to form a first vacancy activation region in the active layer in a portion of the passive waveguide region and the EAM region; removing the vacancy generation layer, the mask pattern, and the passivation layer; forming an upper clad layer on the grating layer; and forming electrodes on the upper clad layer in the LD region and the EAM region.

In an embodiment, the mask pattern may include silicon oxide formed by a plasma-enhanced chemical vapor deposition (PECVD) method.

In an embodiment, the vacancy generation layer may include silicon oxide formed by a sputtering method.

In an embodiment, the mask pattern may include: a first thickness region; and a second thickness region thinner than the first thickness region.

In an embodiment, the active layer may further include a second vacancy activation region formed in the EAM region and adjacent to the first vacancy activation region.

In an embodiment of the inventive concept, a photonic integrated circuit device includes: a substrate including a passive waveguide region, a laser diode (LD) region on one side of the passive waveguide region, and an electro-absorption modulation (EAM) region of another side of the passive waveguide region; an active layer provided on the substrate and configured to extend to the EAM region from the LD region; a grating layer provided on the active layer; a clad layer provided on the grating layer; and electrodes provided on the clad layer in the LD region and the EAM region. Here, the active layer may include a first vacancy activation region provided in a portion of the passive waveguide region and the EAM region.

In an embodiment, the active layer may further include a second vacancy activation region provided in the EAM region.

In an embodiment, the first vacancy activation region may be adjacent to the second vacancy activation region and be provided in the passive waveguide region.

In an embodiment, the photonic integrated circuit device may further include: an antireflection coating provided on one side of the active layer in the EAM region; and a high reflection coating provided in another side of the active layer in the LD region.

In an embodiment, the substrate may further include an amplifier region provided on one side of the EAM region configured to face the passive waveguide region. The active layer may be provided on the amplifier region.

### BRIEF DESCRIPTION OF THE FIGURES

The accompanying drawings are included to provide a further understanding of the inventive concept, and are incorporated in and constitute a part of this specification. The drawings illustrate embodiments of the inventive concept and, together with the description, serve to explain principles of the inventive concept. In the drawings:

FIG. 1 is a flowchart showing a method for fabricating a photonic integrated circuit device according to the present inventive concept;

FIGS. 2 to 12 are process cross-sectional views of a photonic integrated circuit of the inventive concept;

FIG. 13 shows a graph of ERs of a typical active layer according to a modulation voltage;

FIG. 14 shows a graph of ERs of light in an active layer and a first vacancy activation region in an electro-absorption modulation (EAM) region of FIG. 12;

FIG. 15 shows a graph of optical power in the active layer and the first vacancy activation region in the EAM region of FIG. 12;

FIG. 16 is a cross-sectional view showing examples of the active layer, the first vacancy activation region, and a second vacancy activation region in the EAM region of FIG. 12;

FIG. 17 shows a graph of ERs in the active layer, the first vacancy activation region, and the second vacancy region of FIG. 16;

FIGS. 18 to 21 are process cross-sectional views of a photonic integrated circuit of the inventive concept;

FIG. 22 is a cross-sectional view of an example photonic integrated circuit according to the present inventive concept;

FIG. 23 shows a graph of photoluminescence intensities versus wavelength according to the thickness of the mask pattern of FIG. 9; and

FIG. 24 shows a graph of optical spectra according to a modulation voltage of a photonic integrated circuit device of FIG. 22.

### DETAILED DESCRIPTION

Hereinafter, exemplary embodiments of the present disclosure will be described in conjunction with the accompanying drawings. The above and other aspects, features, and advantages of the present disclosure will become apparent from the detailed description of the following embodiments in conjunction with the accompanying drawings. However, it should be understood that the present invention is not limited to the following embodiments and may be embodied in different ways. Rather, the embodiments are provided so that this disclosure will be thorough and complete and will fully convey the concept of the invention to those skilled in the art, and the present invention will only be defined by the appended claims. Throughout this specification, like numerals refer to like elements.

The terminology used herein is for the purpose of describing particular embodiments only and is not intended to limit the scope of the present disclosure. As used herein, the singular forms “a”, “an” and “the” are intended to include the plural forms as well, unless the context clearly indicates otherwise. It will be further understood that the terms “comprises,” “comprising,” “includes” and/or “including,” when used herein, specify the presence of stated features, integers, steps, operations, elements, and/or components, but do not preclude the presence or addition of one or more other features, integers, steps, operations, elements, components, and/or groups thereof. Also, as just exemplary embodiments, reference numerals shown according to an order of description are not limited to the order.

Moreover, exemplary embodiments will be described herein with reference to cross-sectional views and/or plan views that are idealized exemplary illustrations. In the drawings, the thickness of layers and regions are exaggerated for effective description of the technical details. Accordingly, variations from the shapes of the illustrations as a result, for example, of manufacturing techniques and/or tolerances, are to be expected. Thus, embodiments of the present invention should not be construed as limited to specific shapes illustrated herein but are also to include deviations in shapes that result from fabrication.

Typically, for advancement in a photonic link technology, unit devices such as a laser, an optical modulator, an optical waveguide, an optical amplifier or the like are integrated into a single chip, which is called as a photonic integrated circuit device. Among them, the most essential portion playing a role may be the laser and the optical modulator. The light oscillated from the laser is transferred to the optical modulator through a passive optical waveguide, and the optical modulator operates as an electro-absorption modulator configured to absorb and modulate an optical signal input through an application of an inverse voltage.

For fabricating the photonic integrated circuit device, it is important to use an active layer suitable for driving each unit device. An InAlGaAs-based active layer has a greater conduction band offset and a smaller valence band offset than an InGaAsP-based active layer that has been used typically. Accordingly, due to excellent saturation characteristics for serving as the electro-absorption modulator as well as the temperature characteristics for a high-temperature operation, the InAlGaAs-based active layer has been recently used for fabricating various optical devices. However, InAlGaAs has a serious oxidation issue of Al while having the characteristics more suitable for optical devices than InGaAsP, and thus a process difficulty increases and the reliability is degraded when a re-growth process is carried out on the InAlGaAs active layer like in the process of using the InGaAsP active layer. In order to address such issues, a photonic integrated circuit device, in which the same InAlGaAs active layer is used for both the laser and the optical modulator and has the advantage of omitting the re-growth process, has been developed. Accordingly, the issues generated in the re-growth process of InAlGaAs may be prevented. However, due to the same active layer in the whole device the passive optical waveguide region between the laser and the optical modulator causes internal optical losses and limits the modulation characteristics of the optical modulator. Specifically, since a gain at the same wavelength is formed even in the optical waveguide region, a single mode laser oscillation output and a side mode suppression ratio (SMSR) loss are generated and the modulation speed of the optical modulator is reduced due to unnecessary light absorption generated at the same wavelength as that of the optical modulator. Accordingly, preventing such optical losses requires a restrictive operation range of the optical modulator and very large detuning of about 40 nm to about 50 nm between gain spectrum and lasing wavelength. Consequently, it is not possible to optimize sufficient extinction ratio (ER) values of the optical modulator and the linearity and saturation characteristics of the ER important especially in an analog communication device.

In order to fabricate a photonic integrated circuit device for addressing the issues, a band gap of the active layer may be adjusted in a selective growth method. However, for the active layer to which the selective growth has been applied, the thickness and composition of a quantum well layer continuously change in the interface of growth patterns, and thus it is difficult to provide an energy band gap region clearly separated when fabricating the photonic integrated circuit device into which a laser, a modulator, passive devices, or the like are integrated. Consequently, the foregoing may not be regarded as a solution because the optical losses are still generated at a wavelength gradually varying in the interface. Accordingly, in order to address the issues, it is necessary to adjust the band gap through a discontinuous change within a small range as a boundary becomes clear.

In a quantum well intermixing method, the energy band gap in a specific region is adjusted through dispersion of vacancies, ions or the like, and thus, unlike the selective growth, it is possible to fabricate an active layer having a distinct boundary because of the presence of a dielectric passivation layer at a position at which the intermixing has not be performed.

Hereinafter, the method for fabricating the photonic integrated circuit device using the quantum well intermixing method according to the inventive concept will be described.

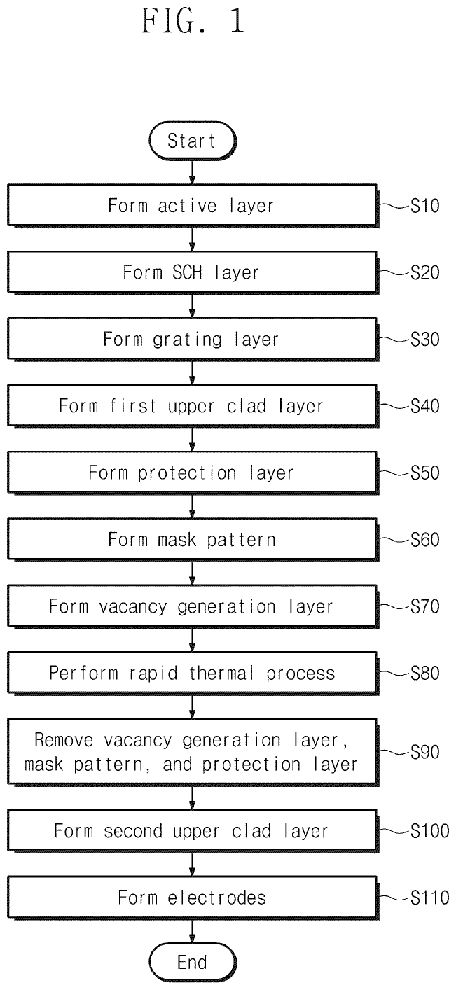

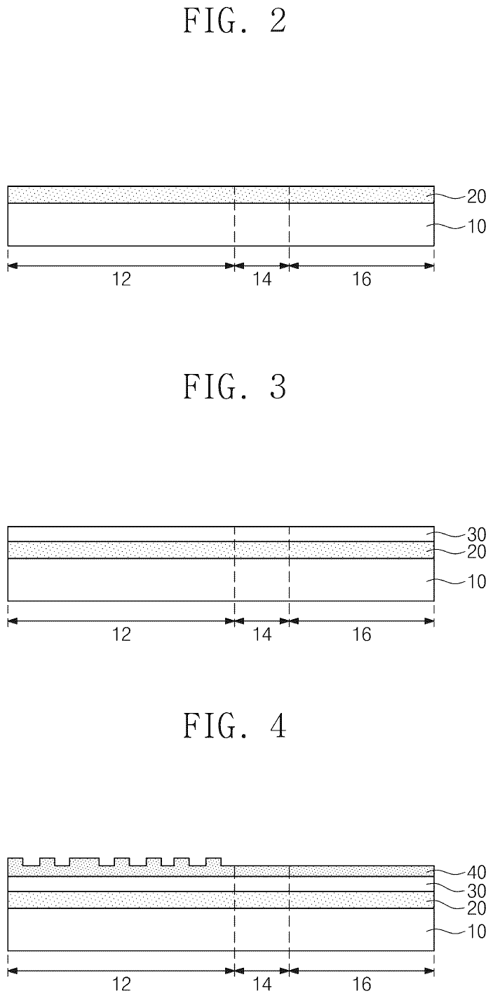

FIG. 1 is a flowchart showing the method for fabricating the photonic integrated circuit device according to the present inventive concept. FIGS. 2 to 12 are process cross-sectional views of the photonic integrated circuit device of the inventive concept.

Referring to FIGS. 1 and 2, an active layer 20 is formed on a substrate 10 (step S10). The substrate 10 may include n-InP. Alternatively, the substrate 10 may include a lower clad layer. The substrate 10 of the lower clad layer may include n-doped InAlAs and undoped InAlGaAs, but the inventive concept is not limited thereto. According to an example, the substrate 10 may include a laser diode (LD) region 12, a passive waveguide region 14, and an electro-absorption modulation (EAM) region 16. The LD region 12 may be formed in one side of the passive waveguide region 14. The LD region 12 may be a distributed feedback (DFB) region in which light 96 is generated. For example, the LD region 12 may have the length of about 300 μm to about 350 μm. The passive waveguide region 14 may be formed between the LD region 12 and the EAM region 16. The passive waveguide region 14 may be a region from which the light 96 is transmitted. The passive waveguide region 14 may have the length of about 50 μm to about 100 μm. The EAM region 16 may be formed in the other side of the passive waveguide region 14. The EAM region 16 may be a region in which the light 96 is modulated.

The active layer 20 may be formed on the substrate 10 in the LD region 12, the passive waveguide region 14, and the EAM region 16. According to an example, the active layer 20 may include a multi-quantum well (MQW) layer having quantum well layers and barrier layers. For example, the active layer 20 may include InAlGaAs.

Referring to FIGS. 1 and 3, a separate confinement heterostructure (SCH) layer 30 is formed on the active layer 20 (step S20). The SCH layer 30 may include undoped InAlGaAs and InAlAs, and p-doped InAlAs and InP.

Referring to FIGS. 1 and 4, a grating layer 40 is formed on the SCH layer 30 (step S30). The grating layer 40 may include p-doped InGaAsP and InP. The grating layer 40 may have unevenness in the LD region 12. The grating layer 40 may have a λ/4 phase transition region in the LD region. The λ/4 phase transition region may be formed at about a ⅔ spot of the entire length of the LD region. The grating layer 40 may be flat or not present in the passive waveguide region 14 and the EAM region 16.

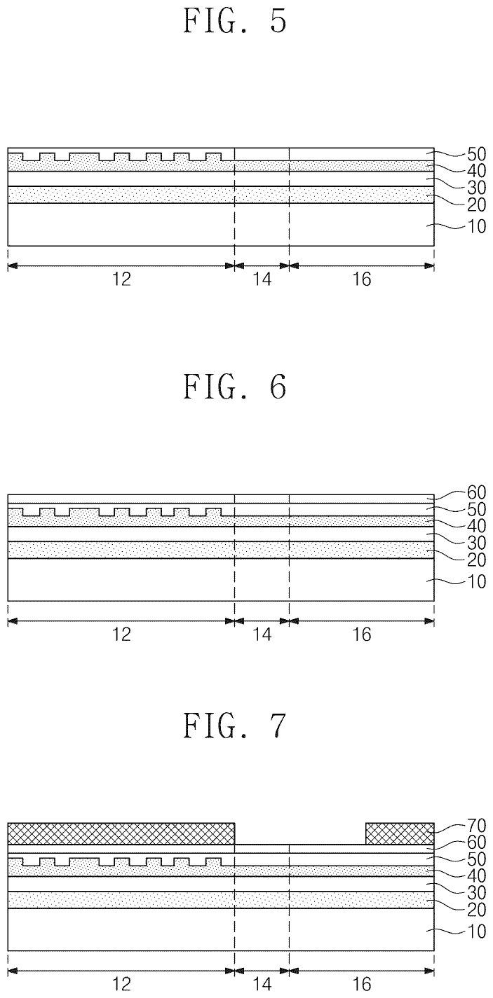

Referring to FIGS. 1 and 5, a first upper clad layer 50 is formed on the grating layer 40 (step S40). The first upper clad layer 50 may include InP p-clad, but the inventive concept is not limited thereto. The top surface of the first upper clad layer 50 may be flat. The first upper clad layer 50 may have the thickness of about 100 nm or thinner.

Referring to FIGS. 1 and 6, a passivation layer 60 is formed on the first upper clad layer 50 (step S50). The passivation layer 60 may include InGaAs. The passivation layer 60 protects the surface of growth layers on the bottom stage.

Referring to FIGS. 1 and 7, a mask pattern 70 is formed on the passivation layer 60 (step S60). The mask pattern 70 may expose the passivation layer 60 in the passive waveguide region 14. The mask pattern 70 may expose a portion of the passivation layer 60 in the EAM region 16. The mask pattern 70 may include silicon dioxide (SiO₂) formed by a plasma-enhanced chemical vapor deposition (PECVD) method. The mask pattern 70 may have the thickness of about 100 nm or thinner. Indium (In) and gallium (Ga) in the passivation layer 60 may be dispersed within the mask pattern 70. The passivation layer 60 may have an interstitial defect of a group 5 element.

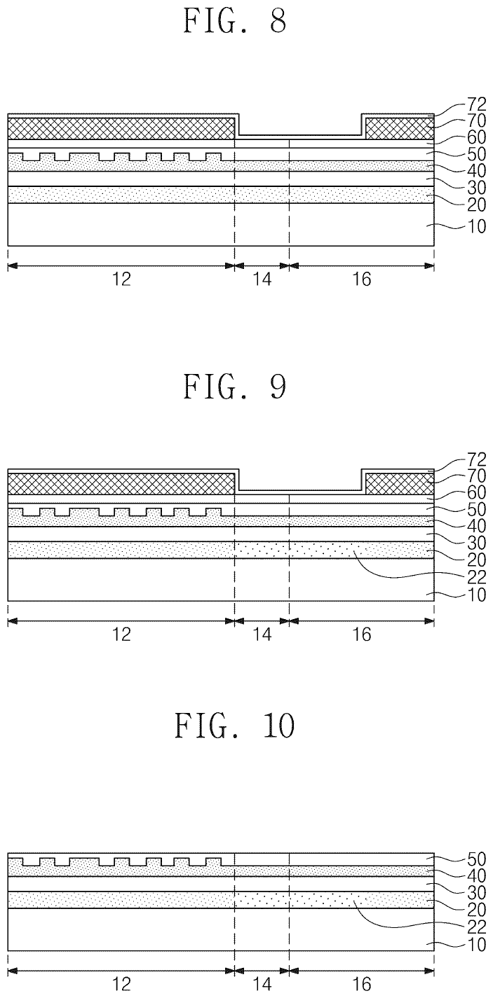

Referring to FIGS. 1 and 8, a vacancy generation layer 72 is formed by a sputtering method using the mask pattern 70 as a deposition mask (step S70). The vacancy generation layer 72 may be formed on the passivation layer 60 and the mask pattern 70. The vacancy generation layer 72 may include a material similar to the material of the mask pattern 70. The vacancy generation layer 72 may include silicon oxide formed by an RF sputtering method. The vacancy generation layer 72 may include an oxide vacancy layer. The vacancy generation layer 72 may have the thickness of about 100 nm or thinner. The passivation layer 60 may be exposed to plasma during deposition of the vacancy generation layer 72.

Referring to FIGS. 1 and 9, a rapid thermal process (RTP) is performed on the substrate 10 to provide a first vacancy activation region 22 of the active layer 20 (step S80). The RTP process may be performed at about 650° C. to about 800° C. for about two minutes. The first vacancy activation region 22 may be aligned with the mask pattern 70. The first vacancy activation region 22 may be formed within the active layer 20 in the passive waveguide region 14. In addition, the first vacancy activation region 22 may be formed within the active layer 20 in a portion of the EAM region 16. The first vacancy activation region 22 may be generated through the quantum well intermixing in the active layer 20.

The quantum well intermixing is performed in various ways such as injecting impurities such as Si, P, Zn, or the like ions or vacancies. Among them, impurity free vacancy enhanced disordering (IFVD) is a method for injecting vacancies of a dielectric thin film into the quantum well and deriving a change in composition on the interface of the quantum well. Unlike other ion injection methods, this method does not cause electrical and optical losses of an optical device due to impurities because atoms in the quantum well are replaced with each other to cause disorder through the vacancies without intervention of the impurities. Accordingly, the quantum well intermixing is the most suitable method for effectively adjusting local energy band gaps.

The quantum well intermixing may be derived through a deposition process of the vacancy generation layer 72 and the RTP of the substrate 10. The quantum well intermixing may be caused by dispersion of the vacancies generated in the deposition process for the vacancy generation layer 72. The mask pattern 70 may block the quantum well intermixing in a portion of the EAM region 16 and the LD region 12 in the RF sputtering process for the vacancy generation layer 72. A portion of the passivation layer 60 exposed by the mask pattern 70 may protect the first upper clad layer 50, generate the vacancies, and disperse the vacancies into the active layer 20.

Through the RTP for the substrate 10, the vacancies in the passivation layer 60 may be dispersed into the active layer 20 and provide the first vacancy activation region 22. Most of the quantum well intermixing may be substantially caused in the RTP. The first vacancy activation region 22 may have a component composition change in the interface between the quantum well layers and the barrier layers of the active layer 20. The first vacancy activation region 22 may have an energy band gap different from that of the active layer 20.

In the first vacancy activation region 22, the light 96 is blue-shifted due to the change in energy band gap of the active layer 20. In addition, the first vacancy activation region 22 may prevent the optical losses generated in the existing optical waveguide, and improve the modulation characteristics of the optical modulator.

Referring to FIGS. 1 and 10, the vacancy generation layer 72, the mask pattern 70, and the passivation layer 60 are removed (step S90). The vacancy generation layer 72, the mask pattern 70, and the passivation layer 60 may be removed in a wet etching process.

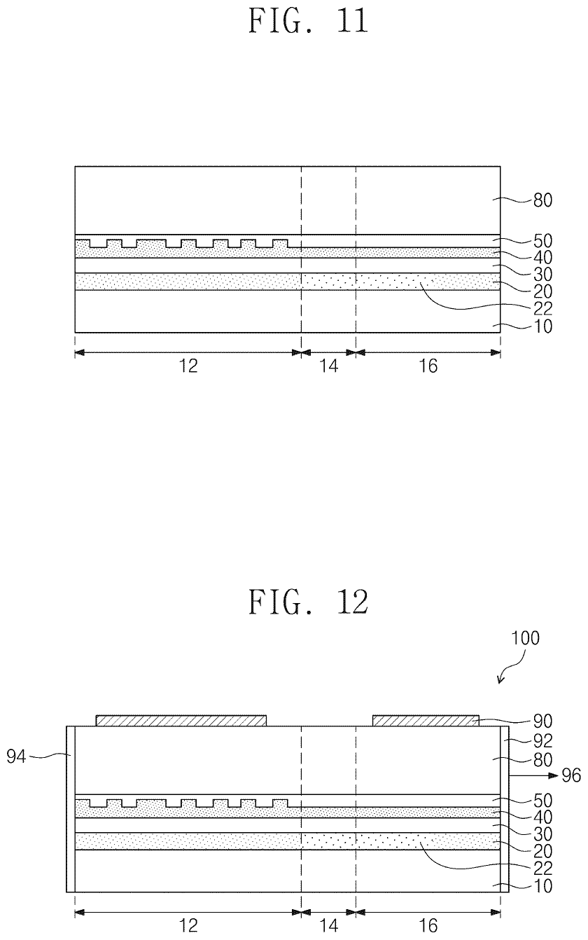

Referring to FIGS. 1 and 11, a second upper clan layer 80 is formed on the first upper clad layer 50 (step S100). The second upper clad layer 80 may be thicker than the first upper clad layer 50. The second upper clad layer 80 may have the same material as the first upper clad layer 50. The second upper clad layer 80 may include p-doped InP, InGaAsP or InGaAs, but the inventive concept is not limited thereto. The second upper clad layer 80 may have the thickness of about 2 μm.

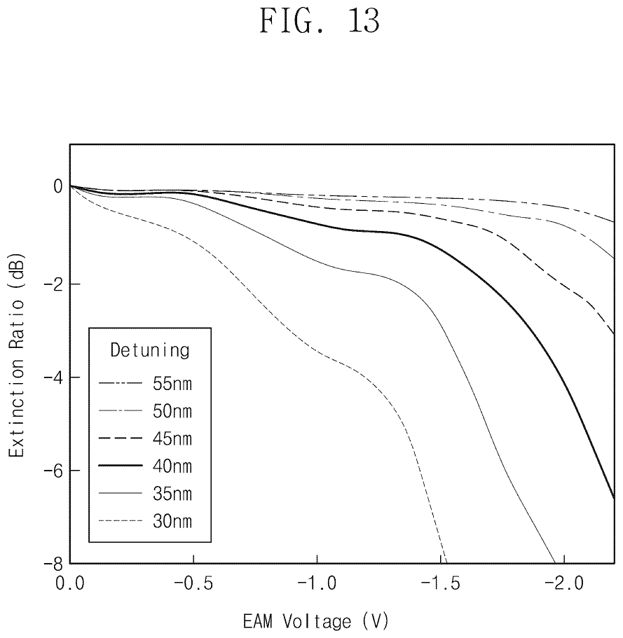

Referring to FIGS. 1 and 12, electrodes 90 are formed on the second upper clad layer 80 in the LD region 12 and the EAM region 16 to fabricate the photonic integrated circuit device 100. The electrodes 90 may include gold Au. Alternatively, the electrodes 90 may include titanium (Ti), platinum (Pt), chromium (Cr), or a laminated structure thereof. An antireflection coating 92 may be formed on one side wall of the substrate 10 and the second upper clad layer 80 in the EAM region 16. The light 96 may be output through the antireflection coating 92. A high reflection coating 94 may be formed on the other side wall of the substrate 10 and the second upper clad layer 80 in the LD region 12. The high reflection coating 94 may reflect the light 96.

FIG. 13 shows ERs of a typical active layer according to a modulation voltage.

Referring to FIG. 13, the typical active layer may have nonlinear ERs corresponding to the modulation voltage of about 0 V to about-2 V in a detuning condition. In other words, the typical active layer may be unsuitable for an analog communication optical device in which a linear increase in ER is important.

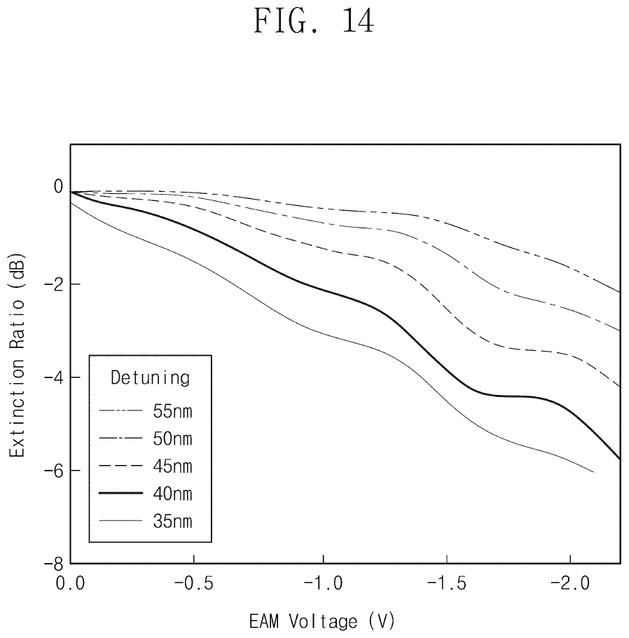

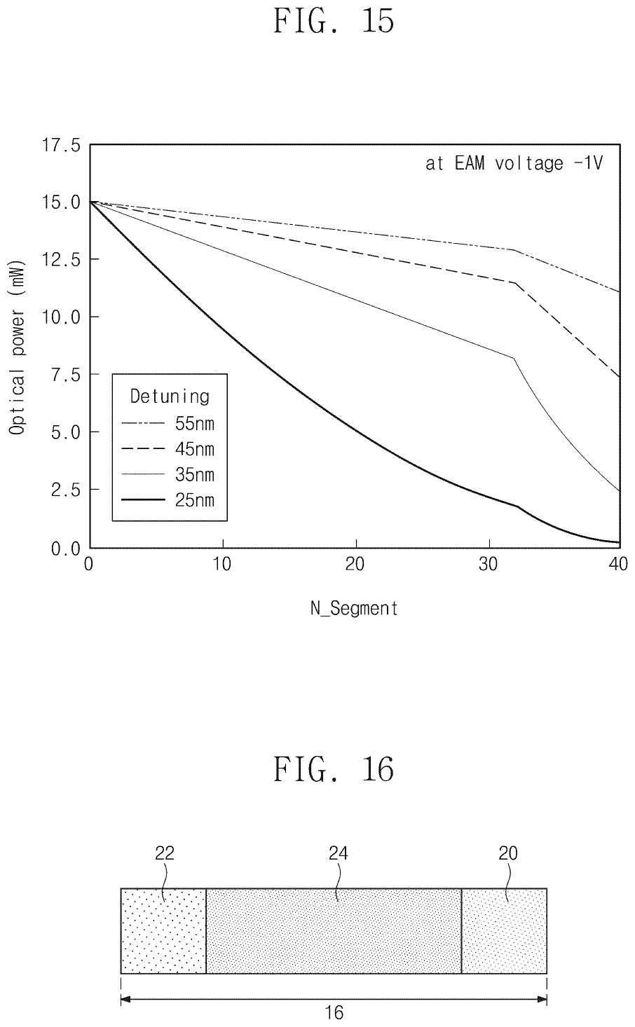

FIG. 14 shows ERs of the light 96 in the active layer 20 and the first vacancy activation region 22 in the EAM region 16 of FIG. 12. FIG. 15 shows optical power of the light 96 inside a cavity in the active layer 20 and the first vacancy active region 22 in the EAM region 16 of FIG. 12.

Referring to FIGS. 14 and 15, the light 96 in the active layer 20 and the first vacancy activation region 22 may have a linear ER in a detuning range of about 35 nm to about 45 nm, and have optical powers decreasing without a saturation region. The active layer 20 and the first vacancy activation region 22 in the EAM region 16 may have a length ratio of about 20% to about 80%. The photonic integrated circuit device 100 according to the inventive concept may increase the modulation characteristics.

FIG. 16 shows an example of the active region 20, the first vacancy activation region 22, and the second vacancy activation region 24 in the EAM region 16 of FIG. 12.

Referring to FIG. 16, the active region 20, the first vacancy activation region 22, and the second vacancy activation region 24 may have linear light absorption and modulation characteristics. The second vacancy activation region 24 may be formed between the first vacancy activation region 22 and the active layer 20 in the EAM region 16. The second vacancy activation region 24 may have the vacancy concentration different from the first vacancy activation region 22. Although not shown, third to n-th vacancy activation regions may be formed between the second vacancy activation region 24 and the active layer 20, but the inventive concept is not limited thereto. The first to n-th vacancy activation regions may be formed based on the thickness or position of the mask pattern 70.

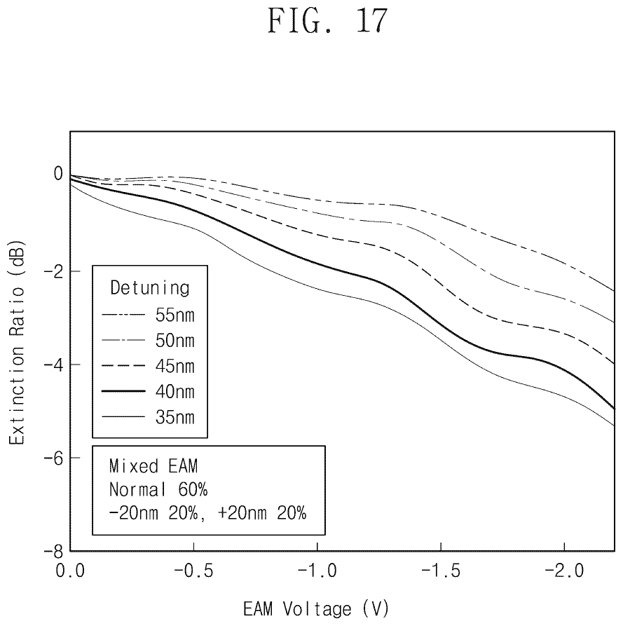

FIG. 17 shows ERs of the light 96 in the active layer 20, the first vacancy activation region 24, and the second vacancy region 24 of FIG. 16.

Referring to FIG. 17, the light 96 in the active region 20, the first vacancy activation region 22, and the second vacancy activation region 24 may have liner ERs. The active layer 20 and the first vacancy activation region 22 may be formed on both sides of the second vacancy activation region 24, and have the lengths of about 20% of the length of EAM region 16. When the length of the second vacancy activation region 24 is about 60 nm, the lengths of the active layer 20 and the first vacancy activation region 22 may be about 20 nm, respectively.

Hereinafter, a method for forming the second vacancy activation region 24 will be described,

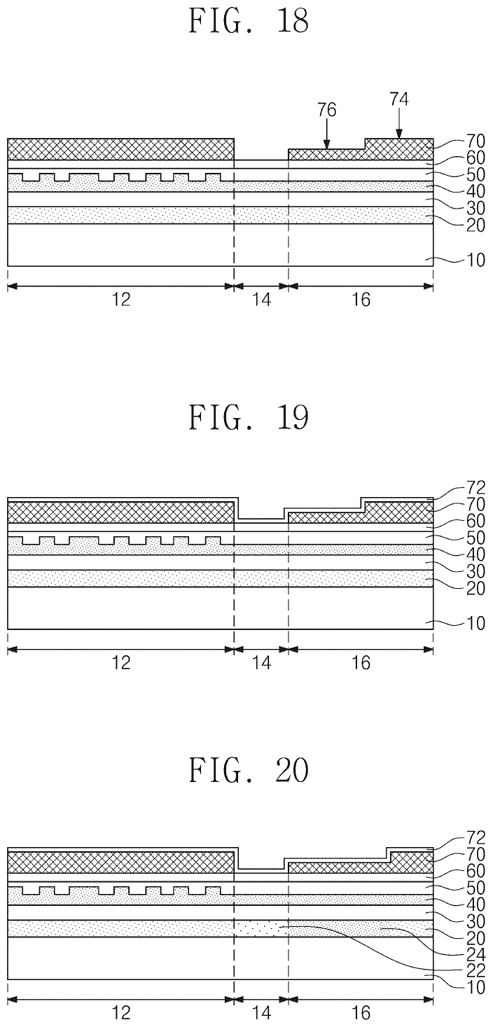

FIGS. 18 to 21 show process cross-sectional views of the photonic integrated circuit device 100 according to the inventive concept.

Referring to FIGS. 1 and 18, the mask pattern 70 having the difference in thickness is formed on the passivation layer 60 (step S60). The mask pattern 70 may expose the passivation layer 60 in the passive waveguide region 14 and cover the passivation layer 60 in the EAM region 16. The mask pattern 70 may have a first thickness region 74 and a second thickness region 76 in the EAM region 16. The second thickness region 76 may be thinner than the first thickness region 74 and be disposed adjacent to the passive waveguide region 14.

A step for forming the active layer 20 (S10), a step for forming the SCH layer 30 (S20), a step for forming the grating layer 40 (S30), a step for forming the first upper clad layer 50 (S40), and a step for forming the passivation layer 60 (S50) may be configured identically to those of FIGS. 2 to 7.

Referring to FIGS. 1 and 19, the vacancy generation layer 72 is formed by the sputtering method using the mask pattern 70 as the deposition mask (step S70).

Referring to FIGS. 1 and 20, the rapid thermal process (RTP) is performed on the substrate 10 to provide the first vacancy activation region 22 in the active layer 20 (step S80). The first vacancy activation region 22 may be formed in the active layer 20 in the passive waveguide region 14. The second vacancy activation region 24 may be formed in the active layer 20 in the EAM region 16. The second vacancy activation region 24 may be aligned with a second thickness region 76 of the mask pattern 70. The second vacancy activation region 24 may have the vacancy concentration different from the first vacancy activation region 22. The vacancy concentration of the second vacancy activation region 24 may be smaller than that of the first vacancy activation region 22.

The step for removing the vacancy generation layer 72, the mask pattern 70, and the passivation layer 60 (S90) and the step for forming the second upper clad layer 80 (S100) may be configured identically to those of FIGS. 10 and 11.

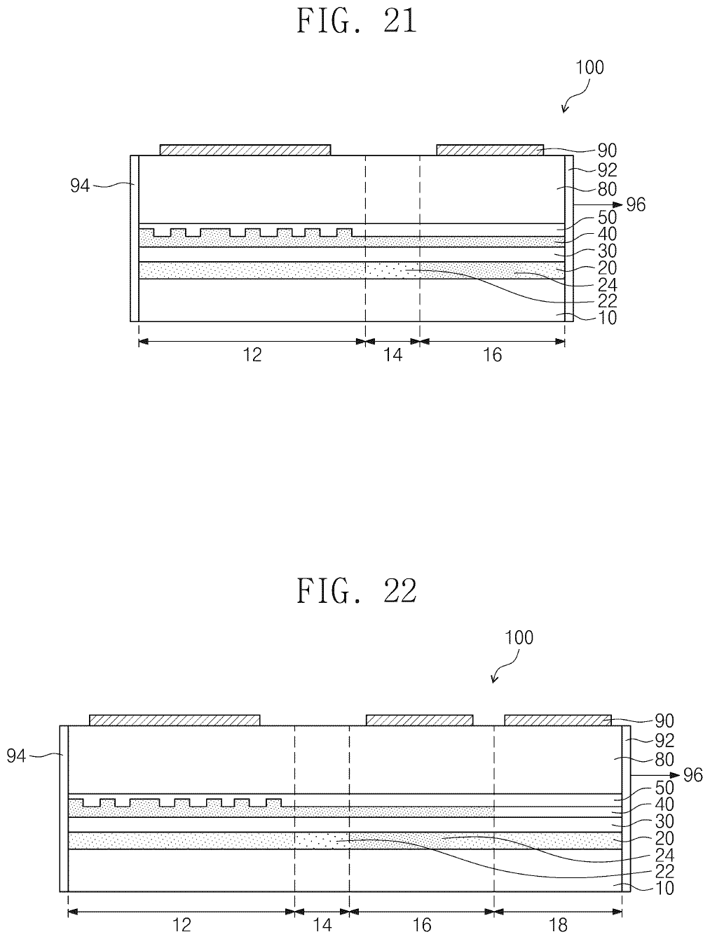

Referring to FIGS. 1 and 21, the electrodes 90 are formed on the second upper clad layer 80 in the LD region 12 and the EAM region 16.

FIG. 22 shows an example photonic integrated circuit device 100 according to the inventive concept.

Referring to FIG. 22, the substrate 10 of the photonic integrated circuit device 100 according to the inventive concept may further include an amplifier region 18. The active layer 20, the SCH layer 30, the grating layer 40, the first upper clad layer 50, and the second upper clad layer 80 may be formed on the substrate 10 of the amplifier region 18. Due to light absorption losses and detuning reduction through the first vacancy activation region 22, the photonic integrated circuit device 100 according to the inventive concept may acquire a sufficient optical gain using the amplifier region 18.

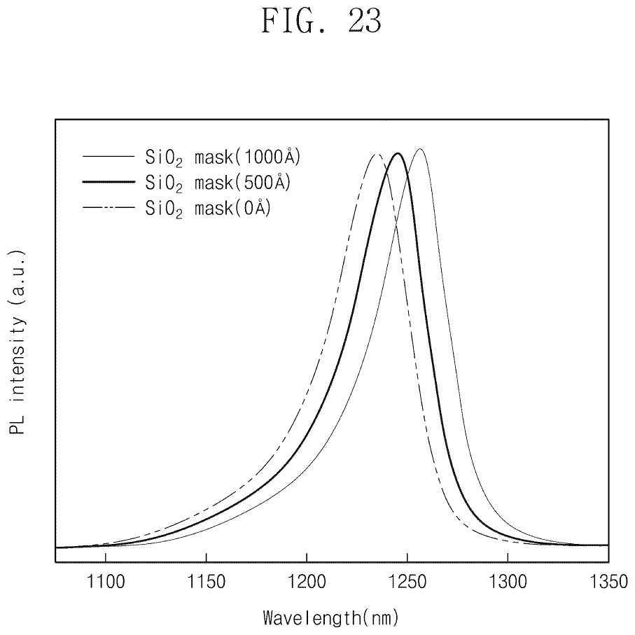

FIG. 23 shows a wavelength of the light 96 and the photoluminescence (PL) intensity according to the thickness of the mask pattern 70 of FIG. 9.

Referring to FIG. 23, the PL peak wavelength of the light 96 may be tuned according to the thickness of the mask pattern 70. When the thickness of the mask pattern 70 is 0, 500 Å and 1000 Å, the PL peak wavelength of the light 96 may appear at wavelengths of 1234 nm, 1243 nm, and 1256 nm, respectively. The PL peak wavelength of the light 96 may be blue-shifted according to the thickness of the mask pattern 70. Accordingly, the photonic integrated circuit device 100 according to the inventive concept may be fabricated in a structure in which the PL peak wavelength shifts to a suitable wavelength according to a process condition of the quantum well intermixing.

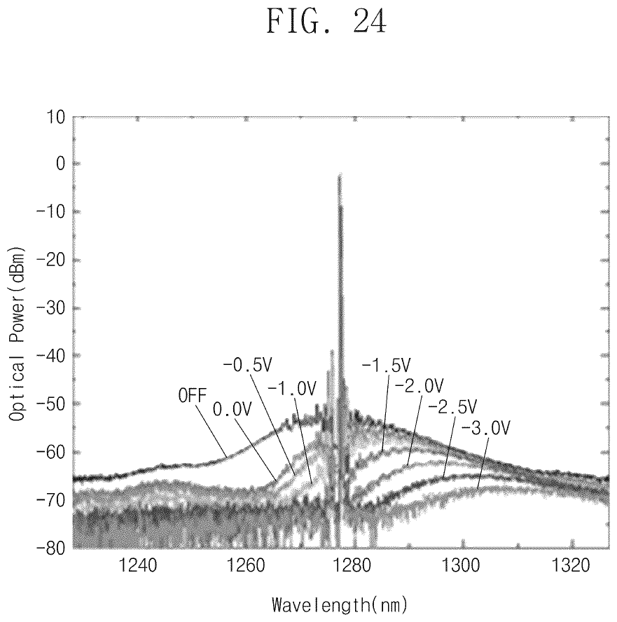

FIG. 24 shows optical spectra according to modulation voltage of the photonic integrated circuit device 100 of FIG. 22.

Referring to FIG. 24, when the substrate 10 and the electrode 90 in the EAM region 16 are applied with an inverse voltage, a sharp dip may appear due to an absorption spectrum in an amplified spontaneous emission (ASE) spectrum. Here, the detuning is smaller than 20 nm. In addition, the dip shows a tendency of moving towards a long wavelength as the application voltage increases. Accordingly, the photonic integrated circuit device 100 according to the inventive concept may reduce a typical degradation of the modulation characteristics due to the optical losses in the typical passive waveguide.

As described above, the method for fabricating a photonic integrated circuit device according to an embodiment of the inventive concept may use the mask pattern as a deposition mask in the sputtering process of the vacancy generation layer to provide the first vacancy activation region in the active layer, increase the productivity and the production yield, and improve the modulation characteristics of the device.

The exemplary embodiments of the present disclosure have been described above with reference to the accompanying drawings, but those skilled in the art will understand that the present disclosure may be implemented in another concrete form without changing the technical spirit or an essential feature thereof. Therefore, the aforementioned exemplary embodiments are all illustrative and are not restricted to a limited form.

What is claimed is:

1. A method for fabricating a photonic integrated circuit device, the method comprising:
forming an active layer on a substrate having a passive waveguide region, a laser diode (LD) region on one side of the passive waveguide region, and an electro-absorption modulation (EAM) region of another side of the passive waveguide region;
forming a grating layer on the active layer;
forming a first upper clad layer on the grating layer;
forming a passivation layer on the first upper clad layer;
forming a mask pattern configured to expose a portion of the passivation layer in the passive waveguide region and the EAM region;
forming a vacancy generation layer on the mask pattern and the passivation layer;
performing a rapid thermal process on the substrate to provide a first vacancy activation region in the active layer in a portion of the passive waveguide region and the EAM region;
removing the vacancy generation layer, the mask pattern, and the passivation layer;
forming a second upper clad layer on the first upper clad layer; and
forming electrodes on the second upper clad layer in the LD region and the EAM region.

2. The method for fabricating a photonic integrated circuit device of claim 1, wherein the mask pattern comprises silicon oxide formed by a plasma-enhanced chemical vapor deposition (PECVD) method.

3. The method for fabricating a photonic integrated circuit device of claim 1, wherein the vacancy generation layer comprises silicon oxide formed by a sputtering method.

4. The method for fabricating a photonic integrated circuit device of claim 1, wherein the active layer comprises a multi-quantum well layer.

5. The method for fabricating a photonic integrated circuit device of claim 4, wherein the multi-quantum well layer comprises InAlGaAs.

6. The method for fabricating a photonic integrated circuit device of claim 1, wherein the first upper clad layer comprises InP.

7. The method for fabricating a photonic integrated circuit device of claim 1, wherein the passivation layer comprises InGaAs.

8. The method for fabricating a photonic integrated circuit device of claim 1, further comprising:
forming a separate confinement heterostructure (SCH) layer between the active layer and the grating layer.

9. The method for fabricating a photonic integrated circuit device of claim 1, wherein the mask pattern comprises:
a first thickness region; and
a second thickness region thinner than the first thickness region.

10. The method for fabricating a photonic integrated circuit device of claim 9, wherein the active layer further comprises a second vacancy activation region formed in the EAM region and adjacent to the first vacancy activation region.

11. A method for fabricating a photonic integrated circuit device, the method comprising:
forming an active layer on a substrate having a passive waveguide region, a laser diode (LD) region on one side of the passive waveguide region, and an electro-absorption modulation (EAM) region of another side of the passive waveguide region;
forming a grating layer on the active layer;
forming a passivation layer on the grating layer;
using, as a deposition mask, a mask pattern configured to expose a portion of the passivation layer in the passive waveguide region and the EAM region to form a vacancy generation layer on the passivation layer;
performing a rapid thermal process on the substrate to form a first vacancy activation region in the active layer in a portion of the passive waveguide region and the EAM region;
removing the vacancy generation layer, the mask pattern, and the passivation layer;
forming an upper clad layer on the grating layer; and
forming electrodes on the upper clad layer in the LD region and the EAM region.

12. The method for fabricating a photonic integrated circuit device of claim 11, wherein the mask pattern comprises silicon oxide formed by a plasma-enhanced chemical vapor deposition (PECVD) method.

13. The method for fabricating a photonic integrated circuit device of claim 11, wherein the vacancy generation layer comprises silicon oxide formed by a sputtering method.

14. The method for fabricating a photonic integrated circuit device of claim 11, wherein the mask pattern comprises:
a first thickness region; and
a second thickness region thinner than the first thickness region.

15. The method for fabricating a photonic integrated circuit device of claim 14, wherein the active layer further comprises a second vacancy activation region formed in the EAM region and adjacent to the first vacancy activation region.

16. A photonic integrated circuit device comprising:
a substrate comprising a passive waveguide region, a laser diode (LD) region on one side of the passive waveguide region, and an electro-absorption modulation (EAM) region of another side of the passive waveguide region;
an active layer provided on the substrate and configured to extend to the EAM region from the LD region;
a grating layer provided on the active layer;
a clad layer provided on the grating layer; and
electrodes provided on the clad layer in the LD region and the EAM region,
wherein the active layer comprises a first vacancy activation region provided in a portion of the passive waveguide region and the EAM region.

17. The photonic integrated circuit device of claim 16, wherein the active layer further comprises a second vacancy activation region provided in the EAM region.

18. The photonic integrated circuit device of claim 17, wherein the first vacancy activation region is adjacent to the second vacancy activation region and is provided in the passive waveguide region.

19. The photonic integrated circuit device of claim 16, further comprising:
an antireflection coating provided on one side of the active layer in the EAM region; and
a high reflection coating provided in another side of the active layer in the LD region.

20. The photonic integrated circuit device of claim 16, wherein the substrate further comprises an amplifier region provided on one side of the EAM region configured to face the passive waveguide region,
wherein the active layer is provided on the amplifier region.
